(19) United States
(12) Patent Application Publication
(10) Pub. No.: US 2006/0237734 A1
(43) Pub. Date: Oct. 26, 2006

(54) Thin-layer light-emitting diode chip and method for the production thereof

(76) Inventors: Johannes Baur, Laaber (DE); Berthold Hahn, Hemau (DE); Volker Harle, Laaber (DE)

Correspondence Address: FISH & RICHARDSON PC, P.O. BOX 1022, MINNEAPOLIS, MN, 55440-1022, US

(21) Appl. No.: 10/567,935

(22) PCT Filed: Aug. 19, 2004
(86) PCT No.: PCT/DE04/01854

§ 371 Date: Feb. 9, 2006

(30) Foreign Application Priority Data
Aug. 29, 2003 (DE) 103 402 71.3

(51) Int. Cl. H01L 33/00

(52) U.S. Cl. 257/98

(57) ABSTRACT

A thin-layer LED chip (5) is claimed, comprising an epitaxial layer sequence (6) that is disposed on a carrier element (2) and contains an electromagnetic-radiation-generating active region (8), and a reflective layer (3) that is disposed on a principal surface of the epitaxial layer sequence (6) facing toward the carrier element (2) and reflects at least a portion of the electromagnetic radiation generated in the epitaxial layer sequence (6) back thereinto, in which a structured layer (1) containing a glass material is applied to a radiation extraction surface (7) of the epitaxial layer sequence (6) facing away from said carrier element (2) and has a structure that includes mutually adjacent protuberances (5) that taper in the direction away from the radiation extraction surface (7) and have a lateral grid size that is smaller than one wavelength of an electromagnetic radiation emitted from the epitaxial layer sequence (6). The structured layer (1) is advantageously applied as spin-on glass and structured by grayscale lithography.

The invention concerns a thin-film light-emitting diode (LED) chip comprising an epitaxial layer sequence that is disposed on a carrier element and includes an electromagnetic-radiation-generating active region, and a reflective layer that is disposed on a principal surface of the epitaxial layer sequence facing toward the carrier element and reflects at least a portion of the electromagnetic radiation generated in the epitaxial layer sequence back thereinto.

It further concerns a method for making such a thin-film LED chip.

A thin-film LED chip is distinguished in particular by the following characteristic features:
applied to or formed on a first principal surface of a radiation-generating epitaxial layer sequence that faces toward a carrier element is a reflective layer that reflects at least a portion of the electromagnetic radiation generated in the epitaxial layer sequence back thereinto;
the epitaxial layer sequence has a thickness in the region of 20 μm or less, particularly in the region of 10 μm; and
the epitaxial layer sequence contains at least one semiconductor layer with at least one surface having an intermixing structure that ideally leads to an approximately ergodic distribution of the light in the epitaxial layer sequence, i.e., it has an insofar as possible ergodically stochastic scattering behavior.

A basic principle of a thin-film LED chip is described for example in I. Schnitzer et al., Appl. Phys. Lett. 63 (16), Oct. 18, 1993, 2174-2176, the disclosure content of which in this respect is hereby incorporated by reference.

Radiation extraction from electromagnetic-radiation-emitting semiconductor chips is lossy, due inter alia to reflection at the interfaces of the semiconductor chip with its ambient owing to the disjunct in the refractive index that occurs there (Fresnel losses).

At the interfaces of GaN-based LED chips (n_{GaN}=2.67) with air (n=1), as is the case for example with thin-film LED chips that are not directly provided with plastic encapsulation, the reflection from the semiconductor chip/air interface can be calculated at about 20%.

One known way to improve radiation extraction is to structure surfaces of the semiconductor chip. Surface structures designed to increase transmission from chip surfaces are known for example from U.S. Pat. No. 5,779,924 A. The LED described therein includes a semiconductor chip whose outermost semiconductor layer has a three-dimensional structure. This facilitates light extraction from the semiconductor chip itself, so that light generated in the chip can to a greater extent make its way out of the semiconductor chip into the ambient epoxy resin.

A disadvantage of this method is that demanding etching processes must be used to create the surface structure of the semiconductor chip. This is especially true of GaN-based semiconductor chips.

In addition, the surface structures described in U.S. Pat. No. 5,779,924 A are difficult if not impossible to combine with intermixed structures of thin-film LED chips, having the purpose of producing at least an approximately ergodic distribution of the electromagnetic radiation in the epitaxial layer sequence.

The object of the present invention is to specify a thin-film LED chip that exhibits improved radiation extraction.

A further object is to specify a method for making such a radiation-emitting thin-film LED chip.

These objects are achieved respectively by means of a thin-film LED chip having the features of claim 1 and a method having the features of claim 7.

Advantageous embodiments and improvements of the thin-film LED chip and the method are specified respectively in Dependent claims 2 to 6 and 8 to 13.

According to the invention, in a thin-film LED chip of the kind cited at the beginning hereof, disposed on a radiation extraction surface of the epitaxial layer sequence facing away from the carrier element is a structured layer containing a glass material and including mutually adjacent protuberances that taper away from the radiation extraction surface, with a lateral grid size that is less than one wavelength of an electromagnetic radiation emitted from the epitaxial layer sequence. The presence of a grid arrangement in this context does not necessarily mean a regular grid arrangement. If the protuberances are disposed in an irregular grid at least in some areas, then the grid size is preferably less, both on the average and at maximum, than one wavelength of an electromagnetic radiation emitted from the epitaxial layer sequence.

As a result, the structure of the structured layer is not optically resolved for the radiation; the refractive index makes a virtually fluid transition from the unstructured and therefore monolithic region of the structured layer to the refractive index of that portion of the structured layer farthest from the radiation extraction surface, which is therefore approximately the refractive index of the ambient medium. The structures of the structured layer therefore bring about a smooth transition for the index of refraction at the interface between the ambient medium and the structured layer. In cases where the structured layer and the thereto-adjacent semiconductor material of the epitaxial layer sequence have similarly high refractive indexes, the refractive index gradient that must be passed through by radiation generated in the epitaxial layer sequence is very low compared to that of an epitaxial layer sequence without an inventively structured layer. The fraction of the electromagnetic radiation that is reflected back into the epitaxial layer sequence on passing through the epitaxial layer sequence/structured layer/ambient is reduced appreciably in comparison to the same system without a structured layer.

The invention is suitable in particular for thin-layer LED chips based on InGaAlN, such as GaN thin-layer LED chips. The group of InGaAlN-based radiation-emitting and/or radiation-detecting chips particularly includes, in the present case, such chips in which the epitaxially produced semiconductor layer sequence, which normally has a layer sequence composed of various individual layers, contains at least one individual layer that comprises a material from the III/V compound semiconductor material system InₓAl_{y}Ga_{1-x-y}N in which 0≦x≦1, 0≦y≦1 and x+y≦1. The semiconductor layer sequence can for example comprise a conventional pn junction, a double heterostructure, a single quantum well structure (SQW structure) or a multiple quantum well structure (MQW structure). Such structures are known to those skilled in the art and thus will not be described in more detail here. In principle, the invention is also suitable for use in radiation-emitting semiconductor chips based on other semiconductor material systems, such as, for example, InₓAl_{y}Ga_{1-x-y}P in which 0≦x≦1, 0≦y≦1 and x+y≦1 and other III/V or II/VI compound semiconductor systems.

The width of the protuberances and the spacing of immediately adjacent protuberances is advantageously less than one wavelength of an electromagnetic radiation emitted from the epitaxial layer sequence.

The height of the protuberances is preferably less than one wavelength of an electromagnetic radiation emitted from the epitaxial layer sequence.

Particularly preferably, it is roughly equal to the grid size.

In an advantageous embodiment of the thin-layer LED chip, the refractive index of the layer lies between the refractive index of a material of a side of the epitaxial layer sequence adjacent the radiation extraction surface and the refractive index of a medium intended as an ambient for the thin-layer LED chip.

The structure preferably comprises protuberances that are, insofar as possible, periodically arranged.

In a preferred embodiment, the protuberances are convexly curved as viewed from the outside. This causes the index of refraction to exhibit a particularly “smooth” transition at the structured layer/ambient interface.

In a particularly advantageous embodiment, the glass material is a spin-on glass. This material is a hardened sol containing for example silicon oxide. The properties and processing options of spin-on glass are known to the skilled person for example from Quenzer et al., “Anodic bonding on glass layers prepared by spin-on glass process: preparation process and experimental results,” Proceedings of Transducers '01/Eurosensors XV, June 2001, the disclosure content of which in this respect is hereby incorporated by reference.

In an inventive method of the kind cited at the beginning hereof, the epitaxial layer sequence disposed on the carrier element is prepared, a layer containing a glass material is applied to a radiation extraction surface of the epitaxial layer sequence facing away from the carrier element, and a structure is introduced, on at least a portion of the layer, that includes mutually adjacent protuberances tapering away from the radiation extraction surface, with a lateral grid size that is less than one wavelength of an electromagnetic radiation emitted from the epitaxial layer sequence.

The layer is advantageously produced by applying a still-molten spin-on glass to the radiation extraction surface and thermally treating said spin-on glass such that it hardens. This procedure can advantageously be performed on-wafer.

In a preferred embodiment of the method, the spin-on glass is applied by spin-coating and/or printing. Spin-coating, in particular, advantageously lends itself to on-wafer processing with little technical expenditure.

In a particularly advantageous embodiment of the method, the structure is introduced into the layer by grayscale lithography.

Grayscale lithography usually includes an exposure step of the layer using a grayscale mask. Grayscale masks, as so-called “analog masks,” permit various radiation intensities, making it possible to produce three-dimensional analog structures, such as curved surfaces, in a single irradiation step. The basic principle is described for example in Sven Warnck, “RELIEF—mass production of low-cost products with microrelief surfaces by CD injection molding,” Information Series of VDI/VDE-Technologiezentrum Informationstechnik GmbH, No. 36-2002, the disclosure content of which in this respect is hereby incorporated by reference.

Here again, the structuring of the layer can advantageously be performed on-wafer, enabling both the application of the spin-on glass and its structuring to be carried out with relatively little technical expenditure, thus permitting low-cost production.

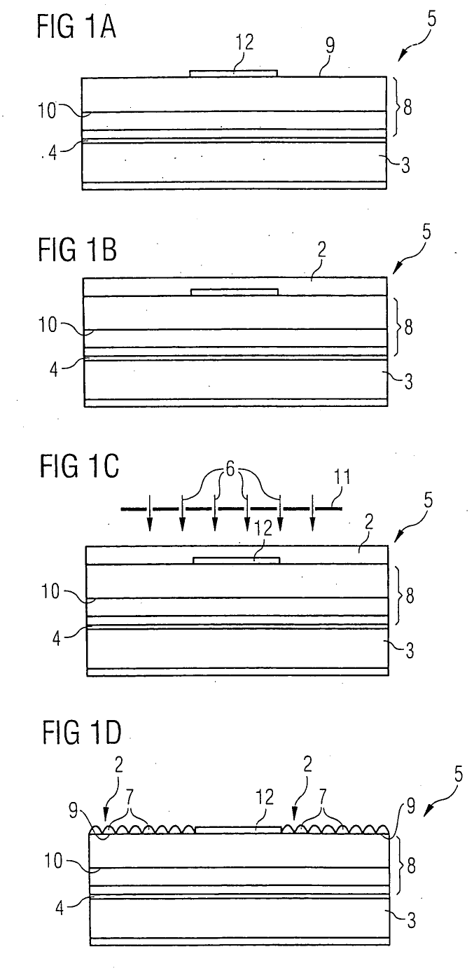

Further advantages, advantageous embodiments and improvements of the thin-layer LED chip and the method for making same will emerge from the exemplary embodiment described hereinafter in conjunction with FIGS. 1a) to 1d).

Therein:

FIGS. 1a-1d show the sequence of a method according to an exemplary embodiment, based on schematic sectional representations of a thin-layer LED chip in four different method stages.

In the exemplary embodiment, like or like-acting elements are identified in the same manner and provided with the same reference numerals. The illustrated layer thicknesses should not be considered true to scale. Rather, they have been represented as exaggeratedly thick and not with the actual thickness ratios that they have with respect to one another.

According to the exemplary embodiment, a thin-layer LED chip 5 is prepared, comprising an epitaxial layer sequence 6 that is disposed on a carrier element 2 and contains an electromagnetic-radiation-generating active region 8, and a reflective layer 3 that is disposed on a principal surface of the epitaxial layer sequence 6 facing toward the carrier element 2 and reflects at least a portion of the electromagnetic radiation generated in the epitaxial layer sequence 6 back thereinto (see FIG. 1a). It should be noted that for the sake of simplicity only one thin-layer LED chip 5 is referred to here. In large-scale chip production, the thin-layer LED chips are usually prepared and processed further in the as yet unsingulated state, that is, on a wafer comprising a plurality of in principle similar thin-layer LED chips that are not singulated into mutually separate thin-layer LED chips until a subsequent stage.

A spin-on glass is then applied, for example by spin-coating, to a radiation extraction surface 7 of epitaxial layer sequence 6 facing away from carrier element 2 (see FIG. 1b).

Any roughnesses on the radiation extraction surface 7 of epitaxial layer sequence 6 that may be introduced unintentionally due to production factors or deliberately to homogenize radiation that is to be coupled out of the epitaxial layer sequence are largely planarized by spin-on glass, i.e., smoothed by the filling in of depressions.

The layer 1 of spin-on glass is then structured by grayscale lithography (see FIGS. 1c, d).

Apart from spin-on glass, additional glass materials or other materials transparent to a radiation generated in the epitaxial layer sequence 6 can also be structured by grayscale lithography. Spin-on glass is particularly well suited for this process, however.

A structure is produced that comprises mutually adjacent protuberances 5 that taper away from the radiation extraction surface 7 of epitaxial layer sequence 6, with a lateral grid size that is less than one wavelength of an electromagnetic radiation generated in the epitaxial layer sequence 6. The height of the protuberances in the direction away from the extraction surface is smaller than one wavelength of an electromagnetic radiation emitted from the epitaxial layer sequence 6, and is preferably roughly equal to the grid size.

Owing to the very small grid size, the protuberances 5 are not optically resolved for the electromagnetic radiation generated in the epitaxial layer sequence 6; from the standpoint of the radiation, so to speak, no individual obstacles exist in the form of the protuberances 5. Instead, the electromagnetic radiation coupled out of the epitaxial layer sequence 6 into the structured spin-on glass layer 1 “sees” a smooth transition of the refractive index from the unstructured region of the structured spin-on glass layer 1, which has the refractive index of the spin-on glass 1 material per se, to the medium (air in this case) in contact with the side of the glass layer facing away from the epitaxial layer sequence 6. Based on current understanding, the material of the structured spin-on glass layer 1 is increasingly “diluted” by the ambient medium in the direction away from the epitaxial layer sequence 6, and in the regions farthest from the epitaxial layer sequence has at least approximately the refractive index of the ambient medium. The fraction of the electromagnetic radiation that is reflected back into the epitaxial layer sequence 6 from the system composed of epitaxial layer sequence 6, structured spin-on glass layer 1 and the ambient medium is reduced appreciably in comparison to the system composed of epitaxial layer sequence 6 and the ambient medium.

An electrical contact layer 9 adjacent the radiation extraction surface 7 is exposed or not covered with material of the structured spin-on glass layer 1 during or after the process of fabricating the structured spin-on glass layer 1.

The invention is not limited to the concretely described exemplary embodiments, but rather extends to all methods and devices having the principal features of the invention. In particular, the invention can be used for thin-layer LED chips having different geometries, different constructions and different semiconductor material systems.

A structured spin-on glass layer 1 according to the invention can also, of course, be used with plastic-molded LED chips. In particular, an inventive structured glass layer, particularly a structured spin-on glass layer, can be applied to semiconductor material at semiconductor/molded plastic interfaces.

Furthermore, inventive structured layers for reducing Fresnel losses can also be applied to a variety of optical systems such as micro optics at solid/air interfaces.

1. A thin-layer LED chip comprising an epitaxial layer sequence that is disposed on a carrier element and comprises an electromagnetic-radiation-generating active region, and a reflective layer that is disposed on a principal surface of said epitaxial layer sequence facing toward said carrier element and reflects at least a portion of the electromagnetic radiation generated in said epitaxial layer sequence back thereinto, wherein-disposed on a radiation extraction surface of said epitaxial layer sequence facing away from said carrier element is a structured layer containing a glass material and exhibiting a structure that includes mutually adjacent protuberances that taper away from said radiation extraction surface and have a lateral grid size that is smaller than one wavelength of an electromagnetic radiation emitted from said epitaxial layer sequence.

2. The thin-layer LED chip as in claim 1, wherein the refractive index of said layer lies between the refractive index of a material of a side of said epitaxial layer sequence adjacent said radiation extraction surface and the refractive index of a medium intended as an ambient for said thin-layer LED chip.

3. The thin-layer LED chip as in claim 1, wherein-said structure comprises protuberances that are largely periodically arranged.

4. The thin-layer LED chip as in claim 1, said protuberances are convexly curved as viewed from the outside.

5. The thin-layer LED chip as in claim 1, wherein said glass material is a spin-on glass.

6. The thin-layer LED chip as in claim 1, the height of said protuberances in the direction away from said radiation extraction surface is smaller than one wavelength of an electromagnetic radiation emitted from said epitaxial layer sequence.

7. A method for making a thin-layer LED chip comprising an epitaxial layer sequence that is disposed on a carrier element and contains an electromagnetic-radiation-generating active region, and a reflective layer that is disposed on a principal surface of said epitaxial layer sequence facing toward said carrier element and reflects at least a portion of the electromagnetic radiation generated in said epitaxial layer sequence back thereinto, wherein said epitaxial layer sequence disposed on said carrier element is prepared, a layer containing a glass material is applied to a radiation extraction surface of said epitaxial layer sequence facing away from said carrier element, and a structure is introduced into at least a portion of said layer, said structure including mutually adjacent protuberances that taper in the direction away from said radiation extraction surface and have a lateral grid size that is smaller than one wavelength of an electromagnetic radiation emitted from said epitaxial layer sequence.

8. The method as in claim 7, wherein-said layer is fabricated by applying a still-molten spin-on glass to said radiation extraction surface and thermally treating said spin-on glass such that it hardens and densifies.

9. The method as in claim 8, wherein the spin-on glass is applied by spin-coating and/or printing.

10. The method as in claim 7, wherein said structure is introduced into said layer by grayscale lithography.

11. The method as in claim 7, wherein-said structure is introduced in such fashion that it comprises periodically arranged protuberances.

12. The method as in claim 7, wherein-the refractive index of said layer lies between the refractive index of a material of a side of said epitaxial layer sequence (6) facing toward said radiation extraction surface and the refractive index of a medium intended as an ambient for said thin-layer LED chip.

13. The method as in claim 7, wherein said structure is introduced in such fashion that the height of said protuberances in the direction away from said radiation extraction surface is smaller than one wavelength of an electromagnetic radiation emitted from said epitaxial layer sequence.

14. The thin-layer led chip as in claim 2, wherein said structure comprises protuberances that are largely periodically arranged.
